(19) United States
(12) Patent Application Publication
(10) Pub. No.: US 2012/0024373 A1
(43) Pub. Date: Feb. 2, 2012

(54) SOLAR CELL MODULE AND METHOD FOR THE MANUFACTURE THEREOF

(75) Inventor: Gerrit Cornelis Dubbeldam, Zevenaar (NL)

(73) Assignee: HELIANTHOS B.V., ARNHEM (NL)

(21) Appl. No.: 13/144,312

(22) PCT Filed: Jan. 12, 2010
(86) PCT No.: PCT/EP10/50289

§ 371 Date: Oct. 18, 2011

(51) Int. Cl. H01L 31/0203; B29C 65/16; B32B 37/06; H01L 31/04

(52) U.S. Cl. 136/259; 156/272.8

(57) ABSTRACT

The invention pertains to a solar cell module comprising a solar cell and an encapsulant, wherein the solar cell module has a current connection area which is connected through an electroconductive connection with an external current carrier, wherein the electroconductive connection is provided with a housing which is bonded to the encapsulant via a laser-welded bond. It has been found that bonding the housing to the encapsulant layer through a laser welded bond makes for a bond which is strong and has good insulating properties.

### CROSS-REFERENCE TO RELATED APPLICATION

This application is a Section 371 National Stage Application of International Application PCT/EP2010/050289 filed Jan. 12, 2010 and published as WO/2010/081801 A2 in English.

### BACKGROUND

The discussion below is merely provided for general background information and is not intended to be used as an aid in determining the scope of the claimed subject matter.

Solar cells, also known as photovoltaic cells, generally comprise a photovoltaic (PV) layer composed of a semiconductor material provided between a front electrode (on the light-receiving side of the cell) and a back electrode (at the back of the cell). The front electrode is transparent, or as thin as possible, enabling incident light to reach the semiconductor material, where the incident radiation is used to generate electric current.

To improve the resistance of solar cells to the environmental conditions to which they are exposed, they are often provided with a protective layer, also indicated as encapsulant layer. An assembly comprising solar cells provided with an encapsulant layer will further be indicated as a solar cell module.

In a solar cell module the current that is generated by the solar cells is collected through one or more current collection areas such as current collection grids or busbars. To be able to use the electrical power generated by the solar cell module, the current collection areas within the module are connected with an external current carrier via an electroconductive connection. External current carriers may, for example, be in the form of wiring or other conductive objects such as strips, etc.

For providing the current collection area with an electroconductive connection with an external current carrier, the encapsulant must be locally removed or penetrated. It is necessary to seal the open spot of the encapsulant from outside influences, for example to prevent penetration of moisture to the electroconductive connection. For that a housing is applied which is bonded to the encapsulant layer. In the context of the present application the word housing refers to an object which surrounds the electroconductive connection and provides it with electrical insulation and protection from mechanical and climatological factors. The housing is bonded to the encapsulant layer.

In the art, junction boxes have been used to provide an electroconductive connection which is protected with a housing. Junction boxes are bonded to the encapsulant layer of a solar cell module by means of adhesives, or via mechanical means. It has been found that when adhesives are used, the width of the adhesive layer between the outer part of the housing and the electroconductive connection has to be relatively large to ensure proper insulation properties of the bond of the housing to the solar cell module. The interface between the housing and the encapsulant layer also has to be relatively large to ensure a bond with adequate mechanical strength. This results in junction boxes with a relatively large size.

Japanese patent application JP 2007 129014 discloses a solar cell module comprising a reverse-surface protection sheet and a terminal box. The terminal box is bonded to the solar cell module by an adhesive portion.

The use of mechanical means to provide bonding of a junction box housing to a solar cell module is also known in the art. However, mechanical means for effecting this bond may be fairly complicated.

There is therefore a need for alternative methods for bonding a housing to a solar cell module provided with an encapsulant. As indicated above, for several reasons the application of adhesives does not result in sufficiently endurable seals. Because the housing must be as small as possible the width of the adhered surface is limited. Further, depending on the nature of the encapsulant, gluing the housing strongly and durable to the encapsulant may not always be possible, because glues are not always compatible to the encapsulant material. As regards solvent bonding the same applies, as it may be difficult to find suitable solvents.

For thermal welding, the temperature of the contact surface most be very high, e.g., of the order of above 250° C. and the parts to be welded must be pressed together. With thermal welding the applied heat must be concentrated in the surfaces to be welded in order to prevent damage of the underlying solar cell structure. The heat must be generated in the surfaces to be welded. Most welding techniques do not meet that demand.

There is need in the art for a method for connecting a solar cell module to an external current carrier via an electroconductive connection provided with a housing which method meets a number of requirements. The bonding of the housing to the solar cell module must be such that long term sealing is obtained. Further, the bonding of the housing to the encapsulant layer should be strong, and electrically non-conductive. An aspect of the present invention provides such a method. Another aspect of the present invention also provides a solar cell module provided with an electroconductive connection with a housing, wherein the housing meets the above requirements. Further advantages of the present invention will become clear from the further specification.

### SUMMARY

This Summary and the Abstract herein are provided to introduce a selection of concepts in a simplified form that are further described below in the Detailed Description. This Summary and the Abstract are not intended to identify key features or essential features of the claimed subject matter, nor are they intended to be used as an aid in determining the scope of the claimed subject matter. The claimed subject matter is not limited to implementations that solve any or all disadvantages noted in the Background.

An aspect of the present invention pertains to a solar cell module comprising a solar cell and an encapsulant, wherein the solar cell module has a current connection area which is connected through an electroconductive connection with an external current carrier, wherein the electroconductive connection is provided with a housing which is bonded to the encapsulant via a laser-welded bond.

An aspect of the present invention also pertains to a method for manufacturing a solar cell module comprising a solar cell provided with a current connection area which is connected through an electroconductive connection with an external current carrier and an encapsulant, wherein the electroconductive connection is provided with a housing which is bonded to the encapsulant, wherein the bonding is effected by laser welding.

It has been found that the use of laser welding makes for a strong bond which is electrically insulating. This combination of properties allows the use of relatively small housings with a relatively small bonding interface while still meeting the requirements placed on electrical insulation and strength of the bond between the housing and the solar cell module.

The solar cell(s) include a photovoltaic layer which has the ability of generating current from incident light, a back electrode layer on one side adjacent and parallel to the photovoltaic layer, and a transparent conductor layer (or front electrode layer) on the other side of, and adjacent and parallel to the photovoltaic layer. The nature of the photovoltaic layer, the transparent conductive oxide, and the back electrode is not critical to the present invention. Suitable materials for these layers are known in the art.

The solar cells are provided with current collection areas as indicated above. This feature is also known in the art and requires no further elucidation.

In one embodiment, the solar cell module is a flexible solar cell foil which comprises solar cell(s) provided with a first encapsulant layer over the transparent conductor layer, and optionally a second encapsulant layer under the back electrode layer.

In another embodiment, the solar cell module is a rigid solar cell module wherein a rigid transparent carrier, for example, a sheet of glass is applied as a carrier over the transparent conductor layer.

The housing is bonded to the encapsulant layer of the solar cell module. In the context of the present specification, an encapsulant layer is a polymer layer which is present above the front electrode or below the back electrode, or on both locations. The encapsulant layer serves to protect the solar cells from the outside world. The encapsulant layer may in itself comprise sublayers with different compositions and properties. Any encapsulant layer present above the front electrode will, as will be evident to the skilled person, be transparent. Encapsulant layers are known in the art.

In the present invention, the housing is bonded to the encapsulant via laser welding.

With laser welding a high intensity laser beam is concentrated at the location of the weld, that is, at the interface between the housing and the encapsulant. To allow proper welding it will be necessary for the laser energy to reach this interface. The laser will be directed at this interface either from the direction of the housing, or from the direction of the encapsulant. To allow the laser light to reach the interface the material between the source of the laser light and the interface should be transparent to laser light. In other words, the wavelength of the laser light and the nature of the polymer may be matched to achieve this.

In one embodiment, the material, be it the housing or the encapsulant, on the side of the interface between the laser and the interface is transparent to the laser light, while the material on the other side of the interface is not transparent to the laser light at the wave-length applied.

In another embodiment, both the material of the housing and the material of the encapsulant are fully transparent at the wavelength applied. In this case a laser-light absorbing material, e.g., in the form of a thin layer of, e.g., carbon, is applied at the interface between the encapsulant and the housing so that heat is generated at that position, which will ensure that welding takes place. The advantage of this embodiment is that welding only takes place at the location where the absorbing material is applied. By selection of a material with a large absorption of the light, the radiation reaching the underlying layers is limited.

By tuning the intensity of the laser beam and the duration of the exposure the generated heat is set sufficient for melting the surface layers of the interface and the time of heating is sufficiently short to limit the penetration depth of the melting zone. The laser beam can be moved over the path to be welded using a commercially available scanning head.

It is noted that other welding techniques known in the art have been found to be not suitable for connecting a housing to an encapsulant of a solar cell module. More in particular, it has been found that with ultrasonic welding proper adhesion was not obtained. Micro-wave welding is considered less suitable, because it may damage the solar cell module because the conducting active layer also absorbs microwave energy.

The housing may be bonded to an encapsulant layer above the front electrode, to an encapsulant layer below the back electrode, or to both.

In one embodiment of the present invention, the housing is applied to one side of the solar cell module only, and not on the other side. This embodiment may be attractive where it is preferred for either the front side or the back side of the solar cell module to be flat. In that case the housing must be adhered to a surface of the solar cell module PV module without the use of a back-plate. This can easily be accomplished within the present invention.

Accordingly, in one embodiment, the housing is applied to one side of the solar cell module only, without connection to the other side of the module being required. The housing may be connected to the encapsulant on the front side of the solar cell module (that is, the light-incident side), or to the back side of the solar cell module.

In one embodiment, where multiple housings are bonded to a solar cell module, all housings are bonded to the same side of the module, be it the front side or the back side of the module. This makes it possible to have one flat surface, which is attractive for further processing, e.g., for adhering it to a carrier. Also where a polymer encapsulant layer is present only on one side of the module, e.g., in the case that the other side of the module is provided with a glass plate, the housing(s) will be bonded to one side of the module only.

In the embodiment where the solar cell module has an encapsulant layer on the front side of the module and a layer on the back side of the module it is also possible for the housing to be bonded to the encapsulant on both sides of the module.

The housing, or at least the part of the housing that will be bonded to the solar cell module, generally is of a polymer material. In one embodiment, the material of the housing, or the relevant part thereof, and that of the encapsulant to which it is going to be bonded are selected such that they may easily be welded together. In one embodiment, the housing, or the relevant part thereof, and the encapsulant are based on the same type of polymer. In this case a bond with particularly advantageous properties may be obtained. For example, both the encapsulant and the housing may be based on a thermoplastic fluoropolymer.

During the welding, it may be required to apply pressure onto the interface to obtain a continuous strong bond. To this end the solar cell module can be supported, e.g., by a rigid support surface, such as a table. Optionally, a pressure can be applied onto the housing. To apply a more evenly distributed pressure onto the housing a pressure member can be used. Preferably, the pressure member is transparent at least for the wavelengths of the laser light spectrum. To avoid interference by scratches or pollutions disturbing the transparency of the pressure member, a disposable pressure member can be used.

### BRIEF DESCRIPTION OF THE DRAWING

Aspects of the present invention is further elucidated by reference to the accompanying drawing.

FIG. 1 is a schematic cross-section of a junction box.

FIG. 2 is a schematic cross-section of an embodiment of a plurality of junction boxes.

FIG. 3 is a schematic cross-section of an embodiment with housings mounted on both sides of a module.

### DETAILED DESCRIPTION OF THE ILLUSTRATIVE EMBODIMENT

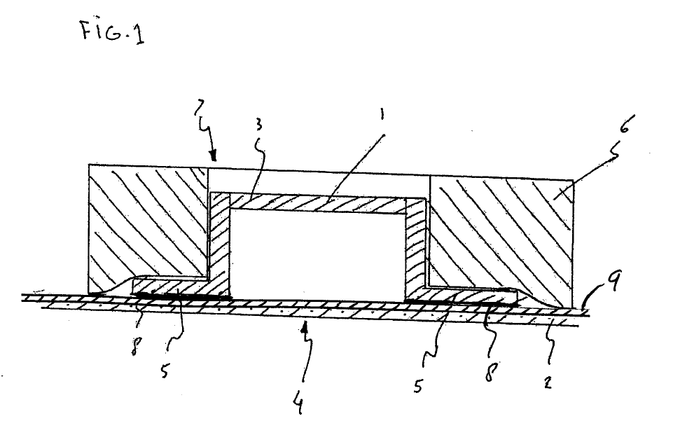

In the drawing FIG. 1 shows schematically in cross section a junction box with a housing 1 for a connection to a cable (not shown) to an electroconductive layer in a foil 2, in particular a solar foil protected by a polymeric encapsulant layer 9. The connection can for example be a clamp connection, a soldered connection or a connection provided by a conductive adhesive. The housing 1 comprises a central body 3 with an open end 4 and is placed with its open end 4 placed on the encapsulant layer 9 of the foil 2. The open end 4 is flanged with outwardly extending flat flanges 5 resting on the encapsulant top layer 9 of the foil 2.

A pressure member 6 of a transparent polymeric material has a central opening 7 fitting over the central body 3 of the housing 1 and resting on the flanges 5 of the housing 1.

A laser welding apparatus (not shown) can be used to weld the flanges 5 onto the foil 2. During welding, a pressure is applied via the pressure member 6 onto the flanges 5. The pressure member 6, the flanges 5 of the housing 1 and the encapsulant layer 9 of the foil 2 are made of polymeric materials which are transparent for the wavelength of the laser light, which is generally about 700-800 nm. By far most polymeric materials are transparent for these wavelengths.

A layer of laser-light absorbing material 8 is applied at the interface between the foil 2 and the flanges 5 of the housing 1. The light absorbing material layer 8 can for example be a carbon layer or a layer of any other suitable type of light absorbing material, for instance known from manufacturing technologies for recordable CD's. The light absorbing material enforces heat generation solely at the position of the weld, so that the heat affected zone is limited to a thin layer on both sides of the weld.

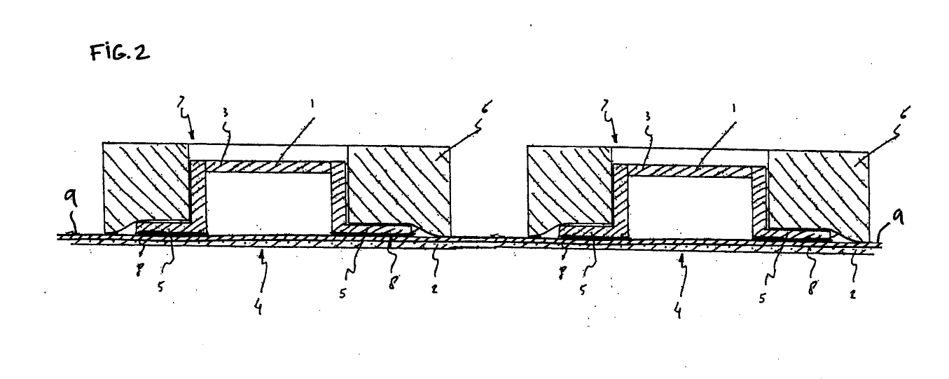

In another embodiment schematically illustrated in FIG. 2, where multiple housings 1 are bonded to a solar cell module, all housings 1 are bonded to the same side of the module, be it the front side or the back side of the module. This makes it possible to have one flat surface, which is attractive for further processing, e.g., for adhering it to a carrier. Also where a polymer encapsulant layer 9 is present only on one side of the module, e.g., in the case that the other side of the module is provided with a glass plate, the housing(s) will be bonded to one side of the module only.

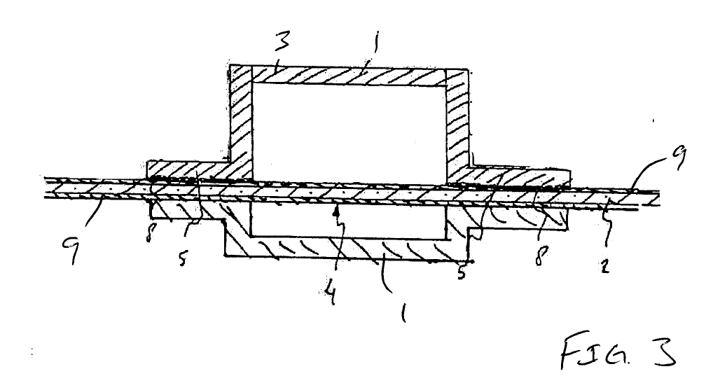

In yet another embodiment schematically illustrated in FIG. 3, where the solar cell module has an encapsulant layer 9 on the front side of the module and a layer on the back side of the module it is also possible for the housings 1 to be bonded to the encapsulant layer 9 on both sides of the module.

1. A solar cell module comprising at least one solar cell and an encapsulant layer, wherein the solar cell module has a current connection area which is connected through an electroconductive connection, wherein the electroconductive connection is provided with a housing which is bonded to the encapsulant layer via a laser-welded bond.

2. The solar cell module according to claim 1, wherein the housing is bonded to an encapsulant layer on one side of the solar cell module only.

3. The solar cell module according to claim 2, wherein multiple electroconductive connections with multiple housings are bonded to the solar cell module and all housings are bonded to the same side, be it the front side or the back side of the module.

4. The solar cell module according to claim 1, wherein the housing is bonded to an encapsulant layer on both sides of the solar cell module.

5. The solar cell module according to claim 1, wherein the module is a flexible module provided with a first encapsulant layer at one side of the module and a second encapsulant layer at the opposite side of the module.

6. The solar cell module according to claim 1 wherein the housing, and the encapsulant layer to which the housing is bonded are based on the same type of polymer.

7. The solar cell module according to claim 6, wherein the housing and the encapsulant layer are based on a thermoplastic fluoropolymer.

8. A method for manufacturing a solar cell module comprising one or more solar cells provided with a current connection area which is connected through an electroconductive connection with an external current carrier, and an encapsulant layer, wherein the electroconductive connection is provided with a housing which is bonded to the encapsulant layer, wherein the bonding is obtained by laser welding.

9. The method according to claim 8, wherein the housing and the encapsulant layer are both transparent to the laser at the wavelength applied, and a laser light absorbing material is applied at the interface between the housing and the encapsulant layer.

10. The method according to claim 8, wherein either the housing or the encapsulant layer are transparent to laser light at the wavelength applied, with the other of housing or encapsulant layer being not transparent to the laser light at the wavelength applied, with the laser being directed at the interface between housing and encapsulant layer from the side of the component which is transparent to the laser light.

11. The method according to claim 8 wherein during welding a pressure is applied onto the housing, while the solar module is supported on a support surface.

12. The method according to claim 11 wherein the pressure is applied by means of a pressure member which is transparent for the laser light at the wavelengths applied.

13. The method according to claim 11 wherein the pressure member is a disposable member.

14. The method according to claim 8 wherein multiple housings are bonded to the encapsulant layer.

15. The method according to claim 14 wherein the encapsulant layer is provided only on one side and the multiple housings are provided only on one side of the solar cell module.

16. The solar cell module according to claim 1, wherein multiple housings are bonded to the encapsulant layer.

17. The solar cell module according to claim 16, wherein the encapsulant layer is provided only on one side and the multiple housings are provided only on one side of the solar cell module.
